(19) United States
(12) Patent Application Publication
(10) Pub. No.: US 2024/0380386 A1
(43) Pub. Date: Nov. 14, 2024

(54) RECONFIGURABLE ACOUSTIC WAVE RESONATOR AND FILTER

(71) Applicants: Arash FOULADI AZARNAMINY, Waterloo (CA); Raafat Rezk MANSOUR, Waterloo (CA)

(72) Inventors: Arash FOULADI AZARNAMINY, Waterloo (CA); Raafat Rezk MANSOUR, Waterloo (CA)

(21) Appl. No.: 18/195,449

(22) Filed: May 10, 2023

(51) Int. Cl. H03H 9/64; H03H 9/02; H03H 9/145

(52) U.S. Cl. CPC H03H 9/6406; H03H 9/02574; H03H 9/145

(57) ABSTRACT

A reconfigurable resonator is provided. The resonator comprises of interdigitated metal electrodes between RF signal and ground planes with additional tuning electrodes that are strategically placed and connected to the ground plane through a plurality of switching element, preferably made of a phase change material. The number and a set of geometric dimensions of each electrode is configured to provide a preferred frequency band. A frequency tuning is achieved by connecting and disconnecting each of tuning electrodes from one of the RF signals or the ground bus-bars using each of switching elements.

### FIELD OF THE INVENTION

The present invention relates in general to reconfigurable resonator devices, and in particular, to tunable piezoelectric resonator based on Surface Acoustic Wave (SAW) technology.

### BACKGROUND OF THE INVENTION

RF filters are the key elements in wireless frontends for filtering the RF signals by passing the desired signal in the pass-band and eliminating the unwanted signals in the rejection band. Surface Acoustic Wave (SAW) technology is traditionally used in many RF filtering applications due to ease of manufacturing, lower cost, and good RF performance. A conventional RF frontend consists of more than tens of SAW filters that each one is allocated for a specific frequency band. These filters are connected through multiplexing switch networks to support multi-band wireless standards. Using individual filters for each band increases the module size, power consumption and cost. Therefore, designing reconfigurable filters that can operate at different frequency bands while maintaining the key RF performance characteristics such as high-quality factor (Q), low insertion loss, good linearity and power handling is necessary for a compact and cost-effective implementation of future RF frontends. Each SAW filter is designed and built using individual SAW resonators that are coupled together. Thus, for implementation of a reconfigurable filter, there is a need for reconfigurable resonators that can be tuned and operated at different resonance frequencies.

The resonance frequency of a SAW resonator depends on the geometric dimensions, such as the spacing between the interdigitated metal electrodes. To be able to adjust the resonance frequency a mechanism is required to vary this electrode spacing. In a conventional SAW resonator since the interdigital electrodes are fixed on a substrate after electrode deposition and patterning it is not possible to adjust the resonance frequency. This disclosure presents a method for construction of reconfigurable SAW resonators that do not need moveable parts and tuning of the resonators is achieved by creating low and high resistance paths between certain electrodes and the ground planes of the resonators using switching elements such as a Phase Change Material (PCM) like Vanadium Dioxide (VO₂) elements that can be easily integrated within the proposed structure of the resonators.

### SUMMARY OF THE INVENTION

In an embodiment, a reconfigurable SAW resonator is provided. The resonator includes interdigitated metal electrodes between RF signal and ground planes with additional tuning electrodes that are strategically placed and connected to the ground plane through a set of vanadium dioxide switching elements. The resonance frequency is tuned between two states, namely high frequency and low frequency states.

In an embodiment, a method of integration of a phase change material, such as vanadium dioxide, switches within the structure of the reconfigurable resonator is provided. The method includes forming tunable resonators with a phase change material switching elements. In this embodiment, each tuning electrode is directly connected to the RF ground plane through PCM switches placed between the electrodes. In a second embodiment of the invention, the tuning metal electrodes are connected together through a floating metal plane above the RF ground plane. A single vanadium dioxide switching element is then placed between the floating and ground planes to connect the tuning elements to the RF ground and tune the resonance frequency of the resonator.

One objective of the presently disclosed reconfigurable resonator is to provide a method for designing and implementing tunable filters to reduce the number of filter products used in current wireless frontends.

Another objective of the presently disclosed reconfigurable resonator is to provide a reconfigurable resonator that has a wide tuning range and has a relatively good RF performance over the tuning range.

Another objective of the presently disclosed reconfigurable resonator is to provide a reconfigurable resonator that is applicable to a wide frequency range. Therefore, it has applications to many different wireless systems.

Another objective of the presently disclosed reconfigurable resonator is to provide a reconfigurable resonator that is smaller in size than current tunable resonators using other technologies such as Micro-Electro-Mechanical Systems (MEMS).

Another objective of the presently disclosed reconfigurable resonator is to provide a less expensive and easier to manufacture device.

### BRIEF DESCRIPTION OF THE DRAWINGS

For a complete understanding of the present invention, reference is now made to the following descriptions taken in conjunction with the accompanying drawing, in which:

FIG. 1 is a top view of an embodiment of a SAW resonator structure according to the prior art;

FIG. 2 is a top view of an embodiment of a reconfigurable resonator structure showing the interdigitated metal electrode configuration;

FIG. 3 is a cross section view of an embodiment of a reconfigurable resonator constructed on a multi-layered substrate structure;

FIG. 4 is a top view of an embodiment of the reconfigurable resonator utilizing tuning metal electrodes that are directly connected to the RF ground plane using vanadium dioxide switches between the electrode fingers;

FIG. 5 is a cross section view of the tuning electrodes and vanadium dioxide switches employed in the reconfigurable resonator structure of FIG. 4;

FIG. 6 is a top view of an embodiment of the reconfigurable resonator utilizing tuning metal electrodes that are connected to a floating metal plane above the RF ground plane. The floating metal plane is then connected to the RF ground through a single vanadium dioxide switch element;

FIG. 7A shows a cross section view of the tuning electrodes, floating plane and vanadium dioxide switch employed in the reconfigurable resonator structure of FIG. 6;

FIG. 7B shows a cross section view of the tuning electrodes, floating plane and vanadium dioxide switch employed in the reconfigurable resonator structure of FIG. 6;

FIG. 8 is an embodiment of the manufactured reconfigurable SAW resonator; FIG. 9 is a graph illustrating measured impedance response for an embodiment of the reconfigurable resonator with two tuning states where both series resonance frequency (Fs) and parallel resonance frequency (Fp) are shifted by almost 20 MHz;

FIG. 10 is a graph illustrating measured quality factor (Q) of a reconfigurable resonator constructed using the disclosed embodiment;

FIG. 11 is an embodiment of the manufactured reconfigurable SAW resonator with tuning metal electrodes that are connected to a floating metal plane above the RF ground plane and a single vanadium dioxide switch element that connects the floating metal plane to the RF ground plane;

FIG. 12 is a graph illustrating measured impedance response for the reconfigurable resonator structure of FIG. 11 with two tuning states;

FIG. 13 is a graph illustrating measured Q of the reconfigurable resonator in FIG. 11;

FIG. 14 is a top view of a modified embodiment of the reconfigurable resonator utilizing tuning metal electrodes that are connected to the RF ground plane through switching elements. The modified configuration of tuning electrodes, allows multiple number of tuning states, namely five frequency tuning states;

FIG. 15 is a graph illustrating measured impedance response for the modified reconfigurable resonator structure of FIG. 14 with five frequency tuning states;

FIG. 16 is a top view of another embodiment of the reconfigurable resonator utilizing tuning metal electrodes that are connected to the RF ground plane through switching elements. The modified resonator structure achieves nine different frequency tuning states;

FIG. 17 is a graph illustrating measured impedance response for the modified reconfigurable resonator structure of FIG. 16 with nine frequency tuning states;

FIG. 18 is photo of an embodiment of the manufactured reconfigurable bandpass filter constructed using the reconfigurable SAW resonator structure disclosed in this invention, and

FIG. 19 is a graph illustrating the measured S-parameter response and transmission states of the manufactured reconfigurable band-pass filter of FIG. 17 with two frequency tuning states.

### DETAILED DESCRIPTION

The following detailed description refers to the accompanying drawings that show, by way of illustration, specific details and embodiments in which the embodiments may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

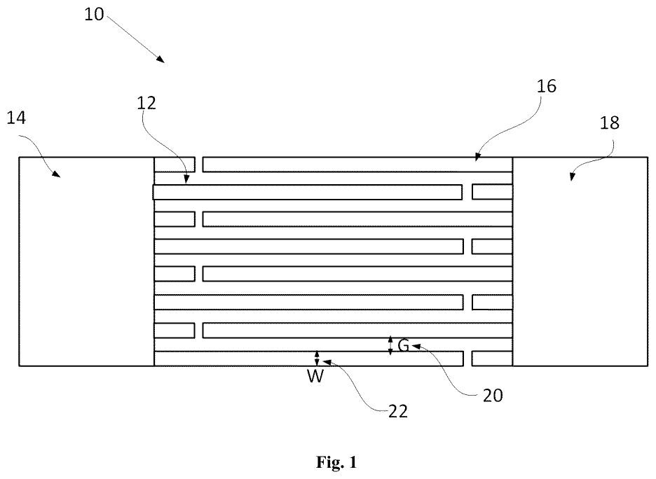

A conventional SAW resonator 10 as disclosed in the prior art Ref. [1], and as shown in FIG. 1, consists of plurality of interdigitated metal (or interdigital transducer, IDT) electrodes 12 connected to the signal bus-bar 14 and a plurality of interdigitated metal electrodes 16 connected to the ground bus-bar 18. The resonance frequency of the SAW resonator 10 is determined by the geometric dimensions of the interdigitated metal electrodes (IDT) 12 and 16, such as the spacing (G) between the electrodes 20 and the width (W) of the metal electrodes 22, with sizes in micron range. Since the geometric dimensions are fixed after manufacturing, the resonance frequency is not adjustable for the SAW resonator 10 disclosed in the prior art.

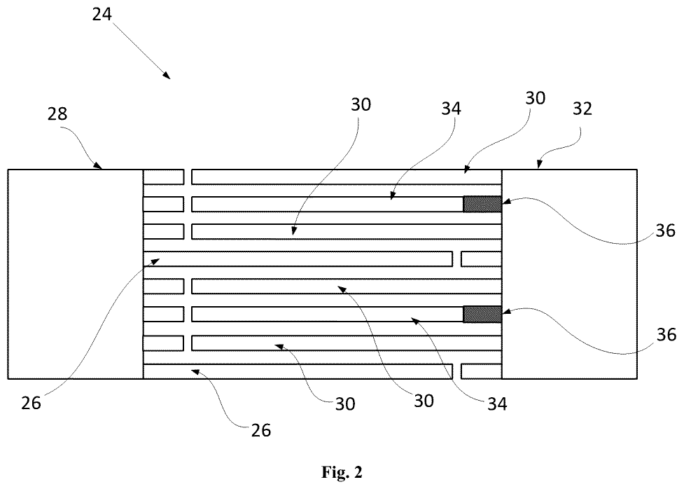

FIG. 2 shows one embodiment of the present reconfigurable resonator 24, which comprises of a plurality of RF interdigitated metal electrodes 26 connected to the RF signal bus-bar 28, a plurality of ground interdigitated metal electrodes 30 connected to the ground bus-bar 32, a plurality of tuning interdigitated metal electrodes used as tuning electrodes 34, and a plurality of switching elements 36.

The interdigitated electrodes comprise of fingers having an electrode pitch or finger pitch which defines a wavelength. When fingers are switched off, the electrode pitch or finger pitch changes defining a new wavelength. The electrode pitch may be the separation distance between two electrode fingers of the same branch of that electrode, which determines a wavelength of the resonant frequency (or the target operating frequency) of a resonator. By applying electrical signals on the electrode a resonant frequency may be excited. The electrode pitch of a set of electrodes may be configured according a first operating frequency of the resonator and the electrode pitch of a second set of the electrodes may be configured according to a second operating frequency.

The resonator may be configured to resonate at a first operating frequency f1, and when switched at a second operating frequency f2 different from the first operating frequency. For example, the reconfigurable resonator 24 may have a center frequency tuning from 700 Mega Hertz (MHz) to 720 MHz while a resonator quality factor (Q) remains above 346 across the entire tuning range.

The switching elements 36 permit the tuning electrodes 34 to be connected or disconnected from one of the RF signal or ground bas-bars. In one embodiment, the tuning electrodes 34 are connected to the ground bus-bar 32 through the switching elements 36. The signal and ground bus-bars 28 and 32 permit the resonator 24 to be electrically connected to other resonators in a filter device.

The IDT electrodes may preferably include an appropriate metal material, for example, Al, Cu, Pt, Au, Ag, Ti, Ni, Cr, Mo, W, or an alloy including any one of these metals as a main component. Further, the IDT electrodes may have a structure in which a plurality of metal films made of these metals or alloys is laminated.

In one embodiment, the switching elements 36 consist of vanadium dioxide material deposited in between and over the fingers of the tuning electrodes 34 and the ground bus-bar 32. In the on-state, the vanadium dioxide material within the switching elements 36, becomes conductive and provides an electrically conductive path in order to short the tuning electrodes 34 to the ground bus-bar 32 and hence tuning the reconfigurable resonator 24 to the low-frequency state. In the off-state, the vanadium dioxide material within the switching elements 36, becomes insulating and provides an electrically open circuit to disconnect the tuning electrodes 34 from the ground bus-bar 32 and hence tuning the reconfigurable resonator 24 to the high-frequency state.

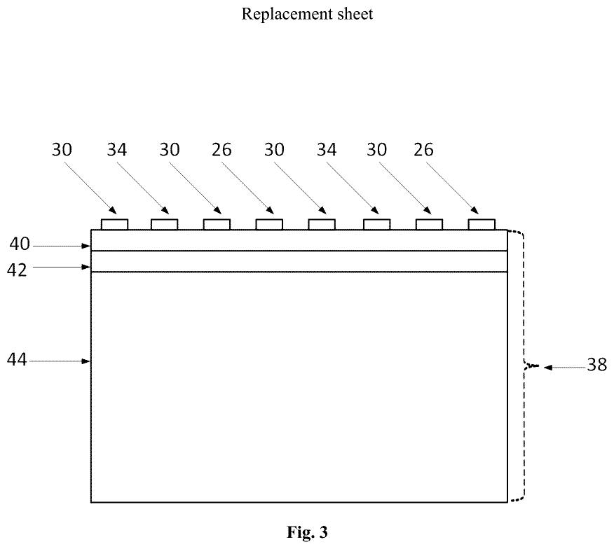

Referring now to FIG. 3, a cross section of the reconfigurable resonator 24 is illustrated. The interdigitated metal electrodes 26, 30, and 34 are deposited on a multi-layered substrate stack 38. The substrate stack 38 comprises of layers of piezoelectric layer 40, dielectric layer 42, and handle substrate 44. The piezoelectric layer may comprise of any piezoelectric material such as Lithium Tantalate, Lithium Niobate, Zinc Oxide or any other piezoelectric material with proper material properties used in conventional SAW resonators (LiTaO₃, LiNbO₃, ZnO, AIN, or lead zirconate titanate). In an embodiment of the disclosed invention as depicted in FIG. 3, the substrate stack 38 comprises of a thin layer of Lithium Tantalate 40 over a thin layer of Silicon Dioxide (SiO2) 42 deposited over a Silicon (Si) substrate material 44. The multi-layered substrate stack 38, known as Piezoelectric on Insulator (POI) technology in the prior art Ref. [2], can be used to confine the acoustic energy within the main acoustic layer 40 and improve resonator performance. Although the embodiments presented in this disclosure are utilizing the POI-SAW technology, they can also be applied to other SAW technologies.

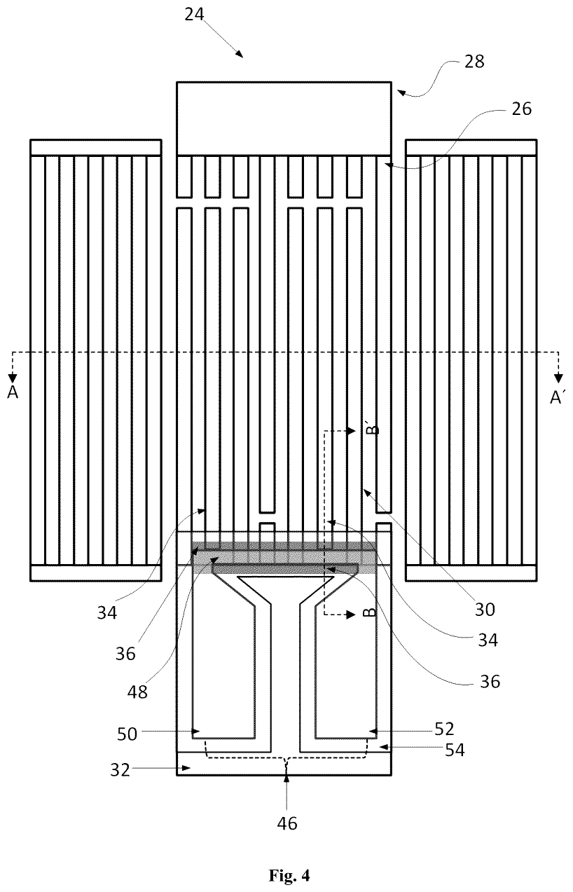

In another embodiment of the present system, as depicted in the top view of FIG. 4, the reconfigurable resonator 24 consists of a plurality of interdigitated metal electrodes 26 connected to the RF signal bus-bar 28, a plurality of interdigitated metal electrodes 30 connected to the ground bus-bar 32, a plurality of interdigitated metal electrodes used as tuning electrodes 34, and a plurality of switching elements 36. The tuning electrodes 34 are directly connected to the ground bus-bar 32 through a plurality of vanadium dioxide switches 36. The resonator structure 24 also includes a heater element 46 which is placed over the vanadium dioxide switches 36. The heater element 46 consists of a resistive layer constructed by deposition and patterning of a metallic thin-film layer 48 such as Chromium (Cr) or Tungsten (W), two Direct-Current (DC) bias electrodes 50 and 52 and a dielectric layer 54 that provides electrical isolation between the heater element 46 and the vanadium dioxide switches 36 and at the same time provides a thermal path for the heat generated in the heater element 46 and transfers it to the vanadium dioxide switches 36.

In the off-state of the reconfigurable resonator in FIG. 4, the vanadium dioxide material within the switching elements 36 are in an electrically insulating state disconnecting the tuning electrodes 34 from the ground bus-bar 32 forcing the resonator to the high frequency state. In the on-state when a DC current is applied between the two DC bias electrodes 50 and 52, the DC current goes through the resistive Cr layer 48 and the generated heat is transferred through the dielectric layer 54 to the vanadium dioxide switching elements 36. The vanadium dioxide material within the switching elements 36 go into an electrically conductive state due to the higher temperature and they provide an electrically conductive path connecting the tuning electrodes 34 to the ground bus-bar 32 forcing the resonator into the low frequency state.

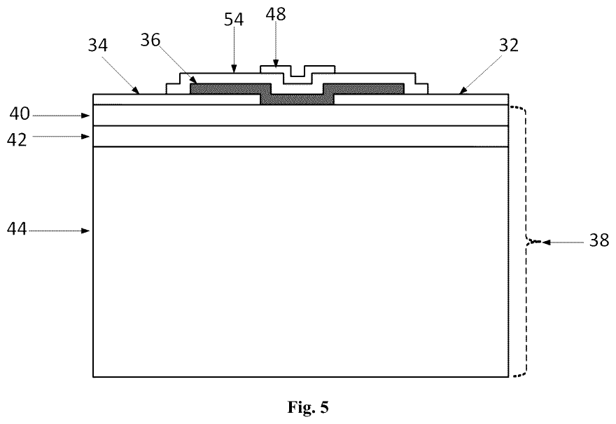

Referring now to FIG. 5, a cross section view of the reconfigurable resonator in FIG. 4 is illustrated for clarity. The metal layers for the tuning electrodes 34 and the ground bus-bar 32 are deposited and patterned on a multi-layered substrate stack 38. The thin-film vanadium dioxide layer 36 is deposited between the gap and over the metal layers for the tuning electrodes 34 and the ground bus-bar 32. A thin-film dielectric layer 54 such as Silicon Nitride (SIN) which has a high thermal conductivity is deposited over the vanadium dioxide switches 36 followed by the deposition of a thin-film resistive Cr layer 48. When the DC bias is applied to the Cr heater, most of the heat is transferred to the switching elements 36 through the SiN dielectric layer 54 for an efficient operation of the resonator in terms of power consumption.

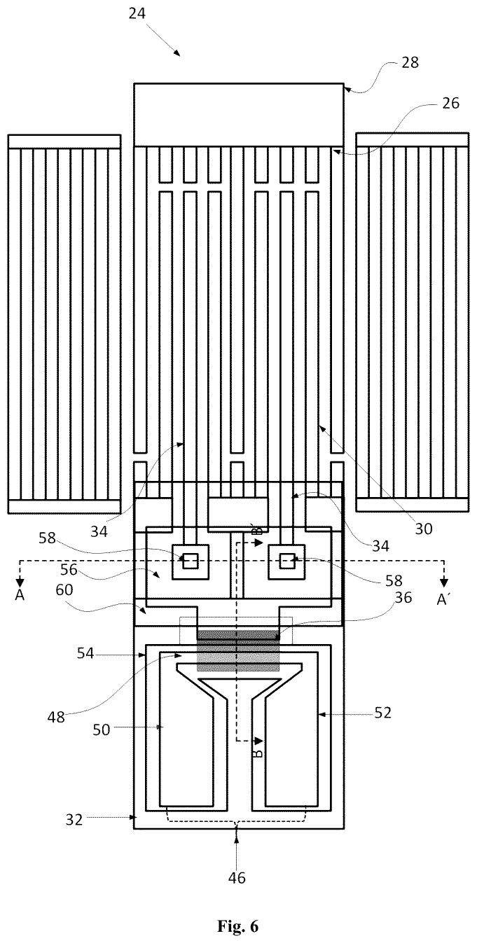

In another embodiment of the disclosed reconfigurable resonator structure, as depicted in the top view of FIG. 6, the reconfigurable resonator 24 consists of a plurality of interdigitated metal electrodes 26 connected to the RF signal bus-bar 28, a plurality of interdigitated metal electrodes 30 connected to the ground bus-bar 32, a plurality of interdigitated metal electrodes used as tuning electrodes 34, a conductive metallic plane 56 over the ground bus-bar 32, a plurality of via connections 58 between the tuning electrodes 34 and the conductive metallic plane 56, and a plurality of switching elements 36. The tuning electrodes 34 are connected to the conductive metallic plane 56 through via connections 58. The conductive metallic plane 56 is connected to the ground bus-bar 32 through switching elements 36. The resonator structure 24 also includes a heater element 46 which is placed over the vanadium dioxide switches 36. The heater element 46 consists of a resistive layer 48 such as Chromium (Cr) or Tungsten (W), two DC bias electrodes 50 and 52 and a dielectric layer 54 that provides electrical isolation between the heater element 46 and the vanadium dioxide switches 36 and at the same time provides a thermal path between the heater element 46 and the vanadium dioxide switches 36.

In the off-state of the reconfigurable resonator in FIG. 6, the vanadium dioxide material within the switching elements 36 are in an electrically insulating state disconnecting the conductive metallic plane 56 and the tuning electrodes 34 from the ground bus-bar 32 forcing the resonator to the high frequency state. In the on-state the vanadium dioxide switching elements 36 provide an electrically conductive path connecting the conductive metallic plane 56 and the tuning electrodes 34 to the ground bus-bar 32 forcing the resonator into the low frequency state. The embodiment presented in FIG. 6 has several advantages such as significantly reduced number of required switching elements 36 and ease of integration and manufacturing of the disclosed reconfigurable resonator structure 24.

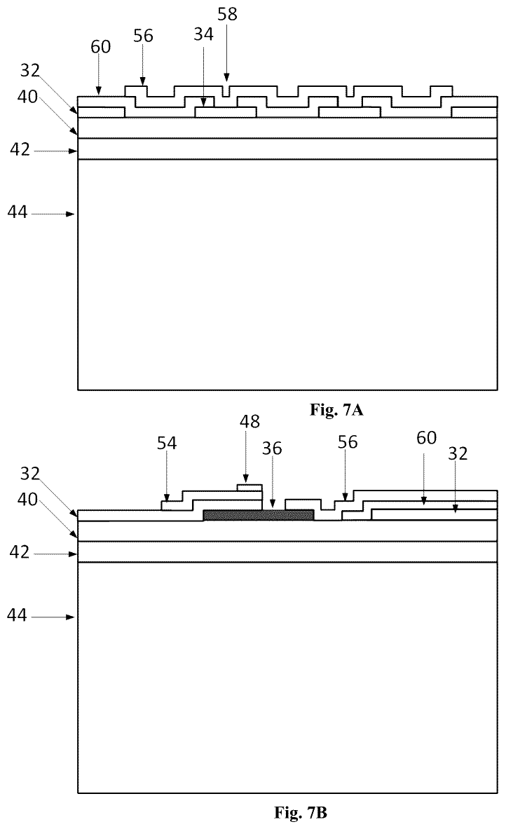

Referring now to FIGS. 7A and 7B, a cross section view of the reconfigurable resonator in FIG. 6 is illustrated for clarity. As depicted in the cross-section image of FIG. 7A, the conductive metallic plane 56 is separated from the ground bus-bar 32 using a thin-film dielectric layer 60, such as silicon nitride. The tuning electrodes 34 are connected to the conductive metallic plane 56 using a plurality of via holes 58. The other cross-section image in FIG. 7B shows the conductive metallic plane 56 inside the active area of the resonator which is separated for the ground bus-bar 32 and the interdigitated metal electrodes using a thin-film dielectric layer 60. The conductive metallic plane 56 is then connected to the ground bus-bar 32 through a vanadium dioxide switch element 36. A thin-film dielectric layer 54 with a high thermal conductivity is deposited over the vanadium dioxide switches 36 followed by the deposition of a thin-film resistive Cr layer 48 used as heater.

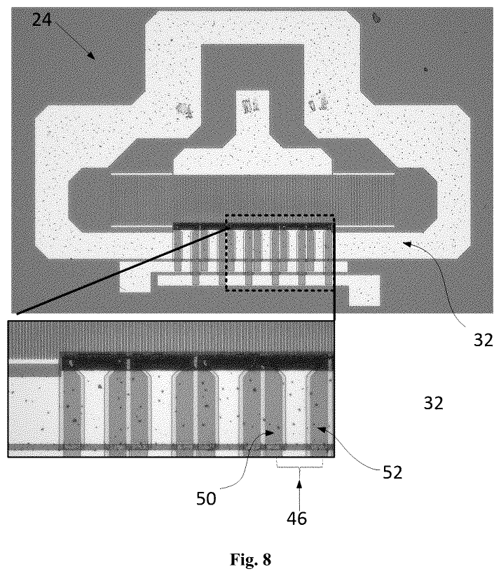

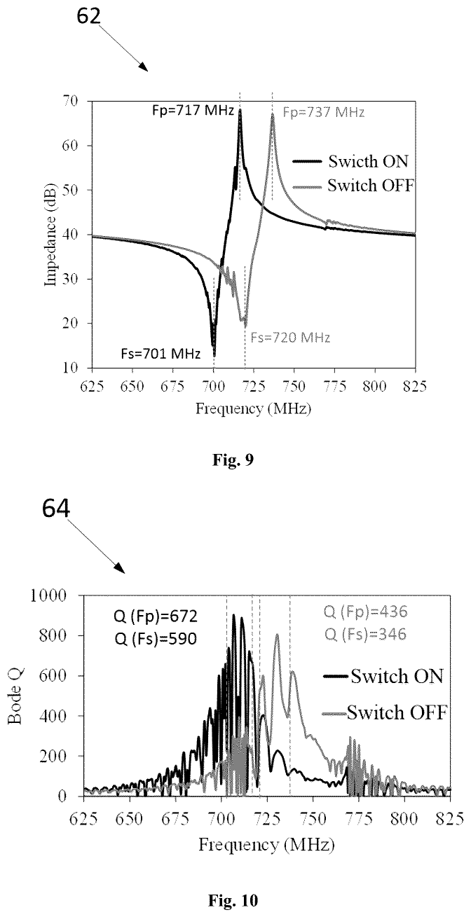

FIG. 8 shows a one-port reconfigurable resonator structure 24 constructed utilizing interdigitated signal and ground electrodes and tuning electrodes. In this case, the tuning electrodes are directly connected to the ground bus-bar 32 through vanadium dioxide switching elements. Five heater elements 46 were connected to the same DC bias electrodes 50 and 52. The measured tuning response of the reconfigurable resonator 24 is graphically illustrated in FIG. 9 for both resonator series and parallel frequencies. As shown in the graph 62 of FIG. 9, the reconfigurable resonator 24 provided a tuning range of approximately 20 MHz from about 720 MHz to about 700 MHz. The measured resonator's quality factor as shown in the graph 64 of FIG. 10, was greater than about 346 for all both the tuning states.

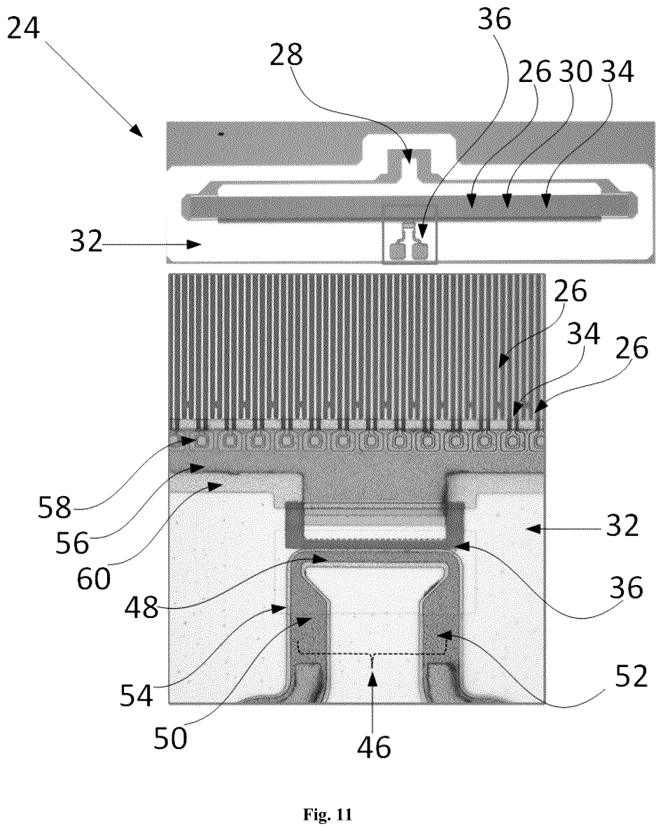

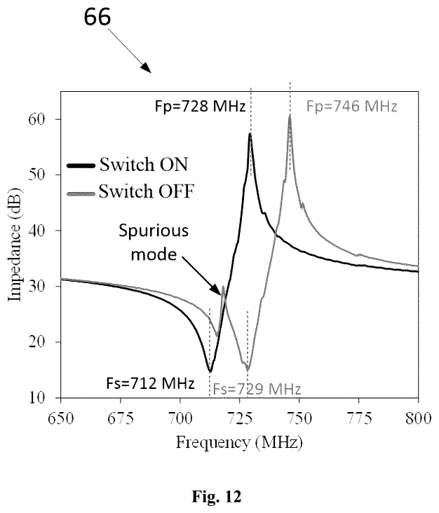

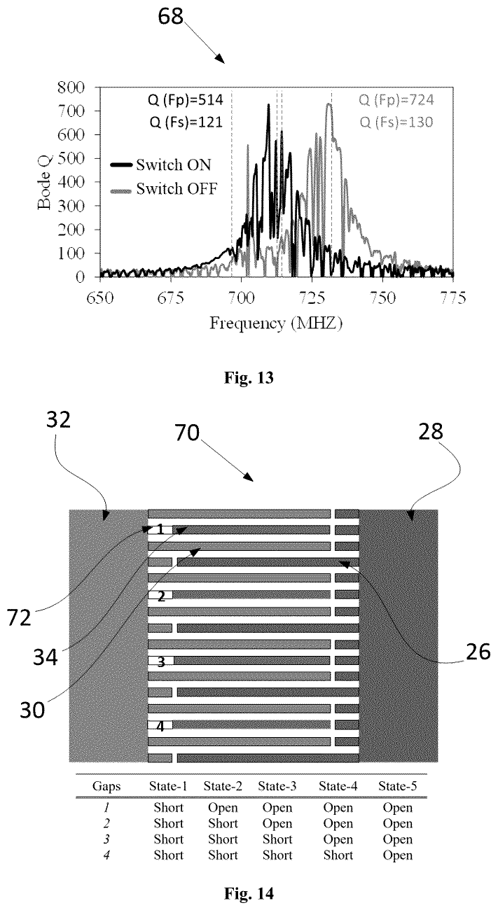

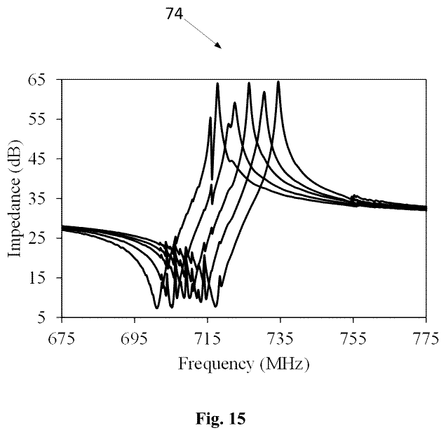

An embodiment of the modified reconfigurable SAW resonator as depicted in the top view of FIG. 6 was manufactured and is illustrated in FIG. 11. In particular, a one-port reconfigurable resonator structure 24 was constructed utilizing interdigitated signal and ground electrodes and tuning electrodes. In the modified embodiment, the tuning electrodes 34 are connected to the ground bus-bar 32 through a conductive metallic plane 56 and a plurality of via connections 58 between the tuning electrodes 34 and the conductive metallic plane 56. The conductive metallic plane 56 is connected to the ground plane 32 through a switching element 36. The measured tuning response and quality factor of the modified reconfigurable resonator 24 is graphically illustrated in FIG. 9 and FIG. 10, respectively.

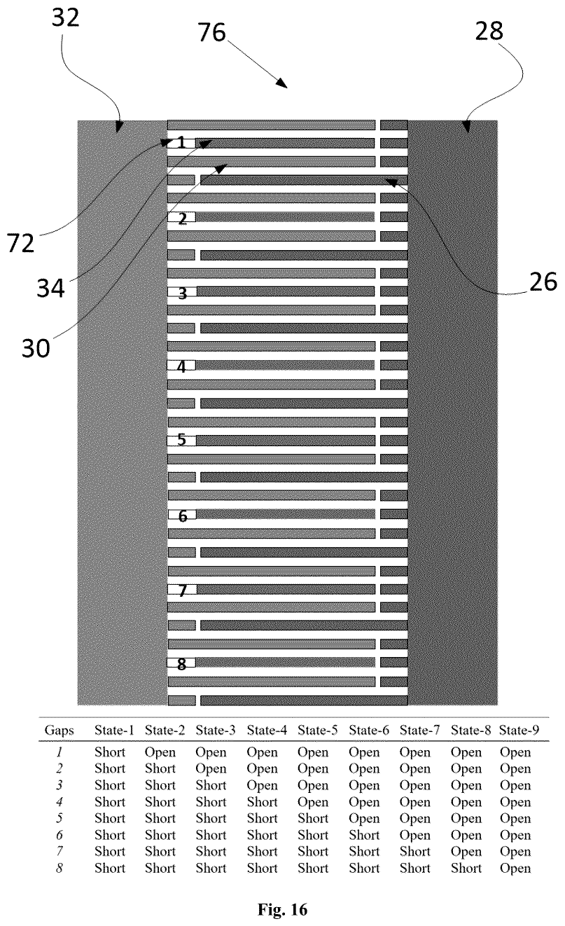

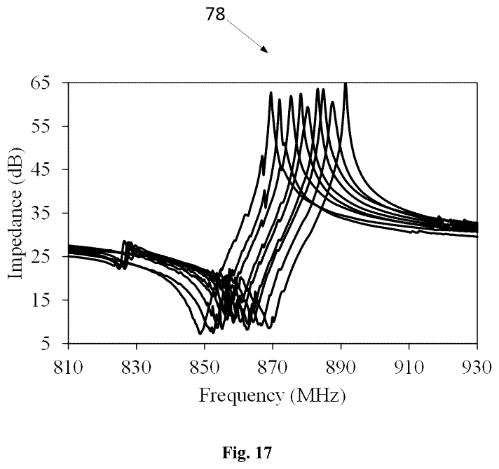

Different embodiments of the reconfigurable SAW resonator with five and nine tuning states are illustrated in FIG. 14 and FIG. 16 with the corresponding states (Short or Open) for each switching element within the resonator structure.

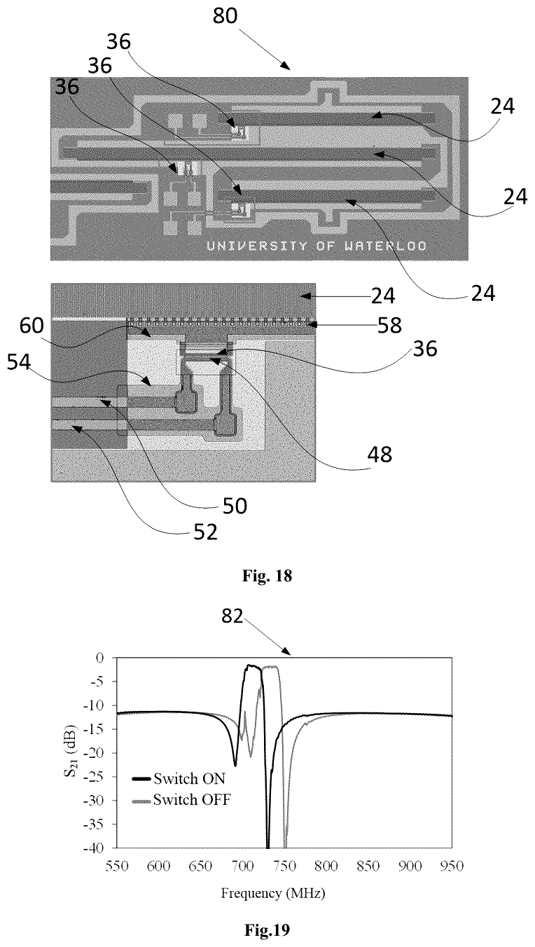

A tunable filter device 80 was constructed as shown in FIG. 18. In particular, a two-port tunable filter structure 80 was constructed utilizing disclosed reconfigurable SAW resonators 24. In this case, the tunable filter consists of three reconfigurable resonators 24 each utilizing a single switching element 36. The switching element 36 consists of a Cr heater element 36 connected to the DC bias lines 50 and 52. The measured tuning response of the tunable filter 80 is graphically illustrated in FIG. 19. As shown in the graph 82 of FIG. 19, the tunable filter 80 demonstrates two frequency tuning states when the switching elements 36 are turned ON and OFF. A tuning range of approximately 20 MHz from about 720 MHz to about 700 MHz was achieved. The measured filters insertion loss as shown in the graph 82 of FIG. 19, was less than about 3 dB for both frequency tuning states.

The presently disclosed reconfigurable resonator allows designing and implementing tunable filters to reduce the number of filter products used in current wireless frontends. The present reconfigurable resonator is smaller in size than other tunable resonators using other technologies such as Micro-Electro-Mechanical Systems (MEMS), yet is less expensive and easier to manufacture. In addition, the present reconfigurable resonator has a wide tuning range and has a relatively good RF performance over the tuning range. The present reconfigurable resonator is also applicable to a wide frequency range. Therefore, it has application to many different wireless systems.

While the disclosure has been made with reference to illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

The resonator may be configured to resonate at a first operating frequency (or first target operating frequency).

The reconfiguration switch may be operable in different configuration or operation states. The reconfiguration switch may be operable in a first operation mode and a second operation mode. For example, the first operation mode may be to select the first resonator, while the second operation mode may be to select by turning off the switches. Other number of switches may also be used in other embodiments.

The resonator device may be incorporated into or used with various types of devices, such as resonators, filters, transducers or other frequency-selective devices in various non-limiting examples. The resonator device may advantageously reduce footprint for multi-frequency applications. Further, the resonator devices may be designed and fabricated for arbitrary coupling of a combination of operating frequencies.

### REFERENCES

[1] U.S. Pat. No. 4,635,009, Ebata, SURFACE ACOUSTIC WAWVE RESONATOR

[2] T. Takai et al., “I.H.P. SAW technology and its application to microacoustic components (Invited),” 2017 IEEE International Ultrasonics Symposium (IUS), Washington, DC, 2017, pp. 1-8

1. A reconfigurable resonator, comprising:
a) a plurality of reconfigurable acoustic wave resonators, each comprising:
i) a plurality of interdigital transducer (IDT) electrodes between an RF signal and a ground bus-bars, wherein a number and a set of geometric dimensions of each of IDT electrode is configured to provide a preferred frequency band,
ii) a plurality of tuning IDT electrodes placed and connected to one of the RF signal or the ground bus-bars through a plurality of switching elements,
wherein a frequency tuning is achieved by connecting and disconnecting the plurality of tuning IDT electrodes from one of the RF signal or the ground bus-bars using the plurality of switching elements by a switch actuation.

2. The reconfigurable resonator of claim 1, wherein the plurality of reconfigurable acoustic wave resonators are Surface Acoustic Wave (SAW), thin film SAW (TF-SAW), temperature compensated SAW (TC-SAW) or XBAR.

3. The reconfigurable resonator of claim 1, wherein each switching element comprises of a phase change material (PCM), selected from a group consisting of vanadium dioxide (VO₂), germanium telluride (GeTe), germanium-antimony-tellurium (GeS-bTe) or a phase change material alloy.

4. The reconfigurable resonator of claim 3, wherein the plurality of switching elements comprising of one or more heater elements configured to switch on and off one or more of the plurality of switching elements, wherein the switch actuation is achieved by application of a DC bias to change a phase of the PCM from insulating to conductive state at a predefined transition temperature and in a reversible fashion.

5. The reconfigurable resonator of claim 1, wherein each switching element comprises of semiconductor switches or MEMS switches.

6. The reconfigurable resonator of claim 1, wherein both a resonator series frequency Fs and a resonator parallel frequency Fp are changed or tuned with the switch actuation.

7. The reconfigurable resonator of claim 1, wherein the plurality of tuning IDT electrodes is configured to switch on and off independently or in a plurality of units, wherein each unit is connected to the bus-bar by one switching element.

8. The reconfigurable resonator of claim 1, wherein the plurality of IDT and tuning IDT electrodes comprising a plurality of fingers, wherein a finger length, a finger width, and a finger spacing, are configured to provide a preferred frequency band.

9. The reconfigurable resonator of claim 8, wherein the plurality of switching elements comprise of the PCM deposited in between and over each finger of each tuning IDT electrode and the RF signal or the ground bus-bar, wherein when heated the PCM within each switching element becomes conductive and provides an electrically conductive path in order to short each tuning IDT electrode to the RF signal or the ground bus-bar and hence tuning the reconfigurable resonator to a low-frequency state, and wherein in an off-state, the PCM within each switching elements becomes insulating and provides an electrically open circuit to disconnect each tuning IDT electrode from the RF signal or the ground bus-bar and hence tuning the reconfigurable resonator to a high-frequency state.

10. The reconfigurable resonator of claim 1, wherein the plurality IDT and tuning IDT electrodes are deposited on a multi-layered substrate stack comprising of a piezoelectric layer, a dielectric layer, and a handle substrate.

11. The reconfigurable resonator of claim 10, wherein the piezoelectric layer comprises of a piezoelectric material, selected from a group consisting of Lithium Tantalate, Lithium Niobate and Zinc Oxide.

12. The reconfigurable resonator of claim 10, wherein the multi-layered substrate stack comprises of a layer of Lithium Tantalate over a layer of Silicon Dioxide (SiO2) deposited over a Silicon (Si) substrate material.

13. The reconfigurable resonator of claim 10, wherein the multi-layered substrate stack comprises of a piezoelectric on insulator (POI) technology to confine an acoustic energy within a main acoustic layer and improve resonator performance.

14. The reconfigurable resonator of claim 4, wherein each heater element comprises of a resistive layer constructed by deposition and patterning of a metallic thin-film layer, two Direct-Current (DC) bias electrodes and a dielectric layer that provides electrical isolation between each heater element and the PCM and provides a thermal path for a heat generated in the heater element and transfers it to the PCM.

15. The reconfigurable resonator of claim 14, wherein the metallic thin-film layer is Chromium (Cr) or Tungsten (W) or Titanium (Ti).

16. The reconfigurable resonator of claim 1, wherein each switching element is independently programmable to enable one or more frequency programming of the reconfigurable resonator.

17. The reconfigurable resonator of claim 1, wherein the plurality of switching elements are integrated monolithically with the reconfigurable resonator using one fabrication process or in a hybrid assembly by flip-chip, epoxy or wire-bonding.
